(19) United States
(12) Patent Application Publication
(10) Pub. No.: US 2008/0212303 A1
(43) Pub. Date: Sep. 4, 2008

(54) DEVICE FOR REDUCING OR PREVENTING EXCHANGE OF INFORMATION

(76) Inventors: Warren Farnworth, Nampa, ID (US); Ross Dando, Nampa, ID (US)

Correspondence Address: GREENBERG TRAURIG, LLP (SV);IP DOCKETING, 2450 COLORADO AVENUE, SUITE 400E, SANTA MONICA, CA, 90404, US

(21) Appl. No.: 11/681,340

(22) Filed: Mar. 2, 2007

(51) Int. Cl. H05K 9/00

(52) U.S. Cl. 361/816

(57) ABSTRACT

A device that is adapted to receive a card including information, such as confidential information, in machine-readable form is disclosed. The device includes a body, wherein at least a portion of the body is made of a material that is adapted to attenuate or disrupt an interrogating signal sent toward the card or a return signal sent from the card to thereby at least reduce the likelihood that the confidential information is read from the card.

### BACKGROUND OF THE INVENTION

1. Technical Field

The current disclosure is generally related to the field of electronic data information exchange, and, more particularly, to a device for reducing or preventing the exchange of information, including confidential information.

2. Description of the Related Art

Congress has recently passed legislation that provides that individuals will be required to carry cards that contain a variety of confidential information in machine-readable format. See the articles entitled “House Backs Major Shift to Electronic IDs” and “Senate Approves Electronic ID Card Bill,” which are submitted herewith by Applicants on an Information Disclosure Statement. According to the first article referenced above, the Department of Homeland Security will be charged with drafting the details of any regulations regarding the new electronic ID card.

Such electronic ID cards will undoubtedly include information that the card owner would like to prevent unauthorized access to by unauthorized personnel or entities. Such information may be confidential in nature. The confidential information may be personal information or business-related information. For example, information such as home address, country of citizenship, Social Security number, driver's license number, etc. may be part of the information contained in the electronic ID card. The legislation mandates that the electronic ID card employ machine-readable technology, although the precise form of such machine-readable technology is not specified. However, such machine-readable technology may include the use of magnetic strips or an RFID tag, for example.

FIGS. 1A-1B schematically depict the theory behind one form of accessing electronically stored data by use of non-contact techniques. As shown in these figures, an interrogating device 10 seeks to access information in electronic form from an interrogated device 12. To do so, the interrogating device 10 generates a signal 14 that is directed toward the interrogated device 12. In some cases, the signal 14 powers up the interrogated device 12 such that it generates a return signal 16 with the required information to the interrogating device 10. Such systems are frequently employed in many aspects of modern life, e.g., toll booths on highways, etc. Bar code scanners are another example of where information may be read from a device without the interrogating device 10 actually contacting the interrogated device 12. In such systems, the bar code scanner simply recognizes a pattern of bar codes on the interrogated device 12 that corresponds to certain information, e.g., the type of product and its price.

Given the ease with which machine-readable information may be accessed, personal and/or confidential information maintained in such a format may be readily accessed by unauthorized personnel and used for unauthorized reasons. For example, maintaining confidential information in machine-readable form may facilitate identity theft by criminals that access the machine-readable information without the knowledge of the card holder.

### BRIEF DESCRIPTION OF THE DRAWINGS

The present disclosure may be understood by reference to the following description taken in conjunction with the accompanying drawings, in which like reference numerals identify like elements, and in which:

FIGS. 1A-1B depict illustrative examples of prior art systems that exchange information electronically;

FIGS. 2A-2D depict various embodiments of a device disclosed herein; and

FIGS. 3A-3C depict yet another embodiment of the device disclosed herein.

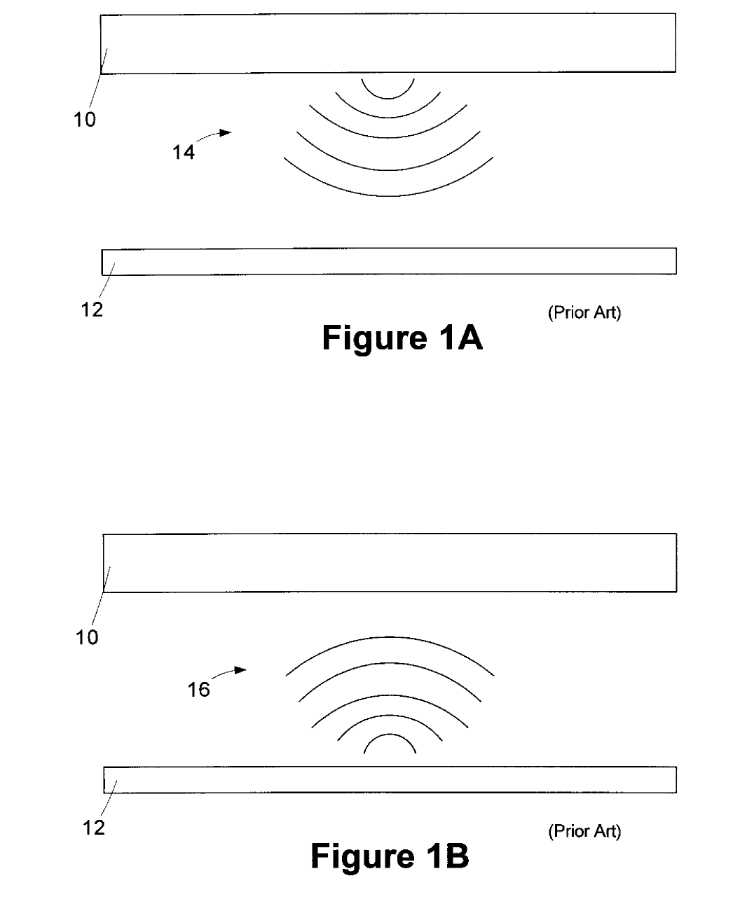

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

In the interest of clarity, not all features of an actual implementation of the device disclosed herein are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure. For purposes of clarity and explanation, the relative sizes of the various features depicted in the drawings may be exaggerated or reduced as compared to the actual size of those features or structures. Nevertheless, the attached drawings are included to describe and explain illustrative examples of the present invention.

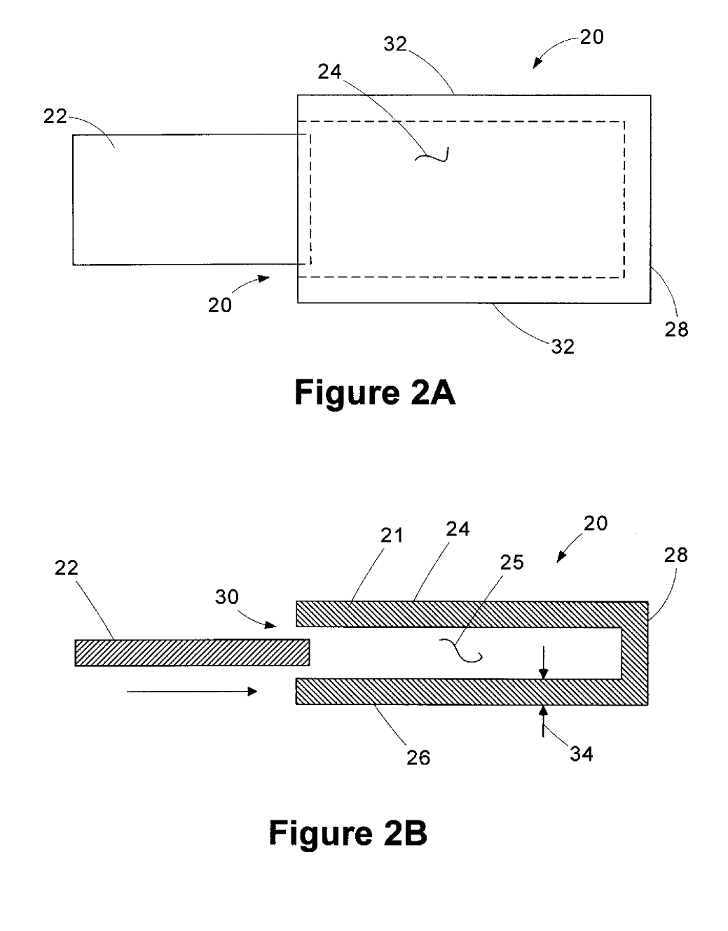

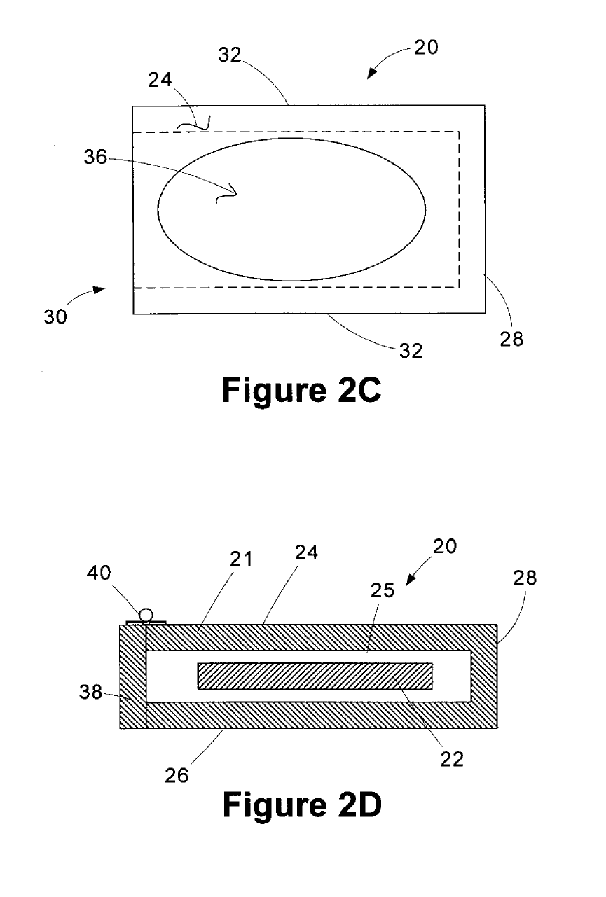

As shown in FIGS. 2A-2B, a shielding device 20 is provided for receiving a card 22 that contains electronic information that is stored in a format such that the information may be read from the card 22 using non-contact interrogating devices or systems, e.g., RFID, active or passive tags, etc. In the embodiment depicted in FIGS. 2A-2B, the shielding device 20 has a generally rectangular body 21 with a front surface 24, a back surface 26, an end surface 28 and side surfaces 32. The shielding device 20 is provided with an opening 30. The shielding device 20 is adapted to have the card 22 inserted through the opening 30 and positioned in the cavity 25 defined by the body 21. The precise form of the card 22 itself may vary as well as the format of the data stored on the card 22.

At least a portion of the body 21 is made from a material that is adapted to disrupt an interrogating signal sent toward the card 22 and/or disrupt a return signal sent from the card 22 to an interrogating device (not shown), or disrupt both signals. The material may also disrupt the ability of the interrogated device to send a return signal, e.g., it may prevent the interrogated device from powering up. It should be understood that, as used herein, the term “interrogating signal” means any form of signal that is used in an attempt to extract electronic information (in any form) from the card 22, e.g., light, radio signals, a signal falling within the electromagnetic spectra, etc. Similarly, it should also be understood that the term “return signal” as used herein means any form of signal by which the card 22 transmits electronic information (in any form) back to an interrogating device. The disruption of the interrogating signal and/or the return signal may be due, at least in part, from the use of a material that absorbs, reflects, or otherwise changes at least a portion of the interrogating signal and/or the return signal.

The material of the body 21 that is used to disrupt an interrogating signal and/or return signal, its thickness, and its location on the shielding device 20 may vary depending upon the particular application. In one embodiment, the entirety of the body 21 of the shielding device 20 may be made of such material. In other cases, only a portion of the body 21, e.g., a portion or the entirety of the front surface 24, may be comprised of such material. Additionally, the material of the body 21 may be opaque or transparent, depending upon the particular material selected.

In one embodiment, the body 21 may be comprised of a metal, such as silver, copper, aluminum, and alloys thereof, and it may have a thickness 34 of approximately 1 Å—2500 μm. The body 21 may be manufactured using a variety of known techniques, e.g., casting, welding, etc. In another example, at least a portion of the body 21 may be made of an electrically conductive transparent material that is adapted to disrupt an interrogating signal and/or a return signal, e.g., indium-tin-oxide (ITO), copper-tin-oxide (CTO), or other similar materials. The thickness and composition of such a transparent material may vary depending upon the particular application.

In general, the body 21 described herein may comprise sufficient material to attenuate the interrogating signal, the return signal or both signals to prevent, hamper or disrupt the transfer of information using such signals. In one example, the body 21 may be designed of a material and configured so as to attenuate a signal by approximately 1-1000 dB. As an even more specific example, the materials of the body 21 and the configuration of the body 21 may be designed so as to attenuate an interrogating or return signal by at least approximately 92 dB. Of course, those skilled in the art will understand that the exact materials employed in all or a portion of the body 21, as well as the thickness and positioning of such materials, may vary depending on a variety of factors, such as anticipated strength of the interrogating and/or receiving signal, the type of device employed (active or passive device), the distance between the source of the signal and the body 21 during anticipated interrogating operations, etc. Of course, these illustrative factors are by no means exhaustive. The type, characteristics and thickness of the material selected to attenuate the signal(s) may be determined based on the characteristics and strength of the anticipated interrogating system, the interrogating signal and the return signal.

FIG. 2C depicts one particularly illustrative example of the shielding device 20 wherein a portion 36 of the body 21 is comprised of a transparent material like that described above. The remainder of the body 21 shown in FIG. 2C may be comprised of a metal or other material. By having a portion 36 of the shielding device 20 transparent, the owner of the card 22 may quickly determine that the card 22 is inside the shielding device 20 by visual inspection and/or show the card 22 to authorized personnel when required to do so without removing the card 22 from the shielding device 20.

FIG. 2D depicts yet another illustrative embodiment of the shielding device 20. As shown therein, a door 38 is provided to cover the opening 30. The door 38 is hinged to the body 21 by a spring-loaded hinge 40. The presence of the door 38 reduces the likelihood that the card 22 may inadvertently fall out of the shielding device 20. However, the shielding device 20 may be provided with other mechanisms to aid in retaining the card 22 in the shielding device 20. For example, a strap may be positioned across the opening 30 wherein one end of the strip is removably coupled to a portion of the body 21 by a variety of techniques, e.g., a Velcro attachment, a button, etc. In general, the cavity 25 of the shielding device 20 is sized in an effort to secure maintain the card 22 within the device 20 without damaging the card 22.

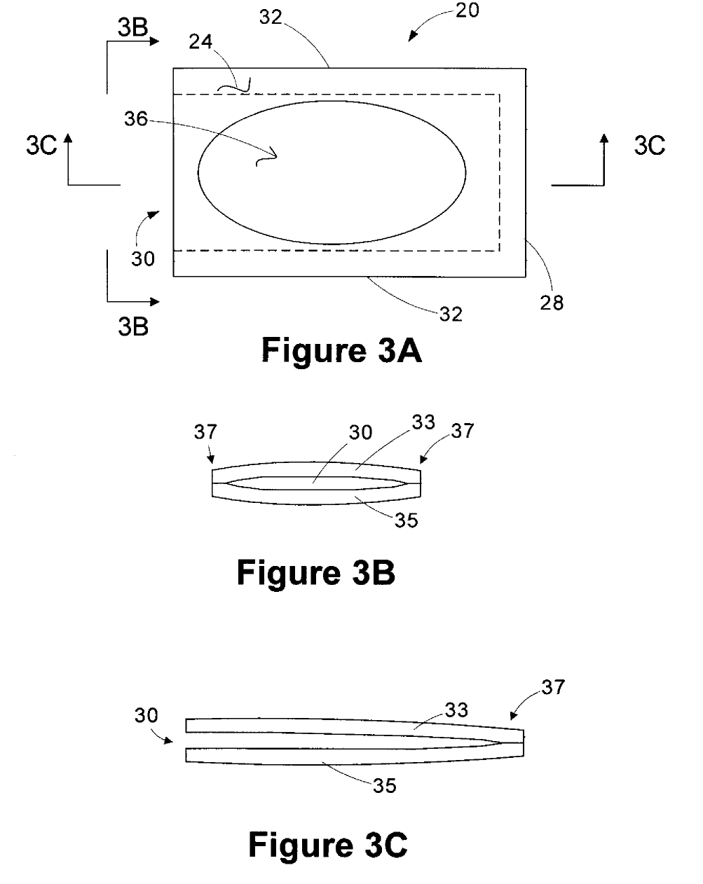

FIGS. 3A-3C depict yet another illustrative example of the shielding device 20, having a pouch-type configuration as opposed to the generally box-shaped design depicted in FIGS. 2A-2B. More specifically, the shielding device 20 depicted in FIGS. 3A-3C comprises first and second layers of material 33, 35 that are coupled or joined together along the edges 37 of those layers of material. The edges 37 may be joined by a variety of known techniques, e.g., welding, brazing, gluing, etc. The card 22 is adapted to be positioned within the device 20 via the opening 30. A door or flap (not shown) may be provided over the opening 30 if desired.

Through use of the present shielding device 20, the owner of the information contained on the card 22 may limit or prevent unauthorized access to the information contained on the card 22. When the owner is convinced that an authorized person or entity is appropriately seeking the information on the card 22, the owner of the card 22 may then remove the card 22 from the shielding device 20 and present it to the authorized person.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device that is adapted to receive a card comprising information in machine-readable form, the device comprising:
a body, wherein at least a portion of the body is comprised of a material that is adapted to attenuate an interrogating signal sent toward the card or a return signal sent from the card.

2. The device of claim 1, wherein the entirety of the body is comprised of the material.

3. The device of claim 1, wherein the material is adapted to attenuate at least one of the interrogating signal and the return signal by approximately 1-1000 dB.

4. The device of claim 1, wherein the information is confidential information.

5. The device of claim 1, wherein the material comprises a metal.

6. The device of claim 1, wherein the material is a transparent material.

7. The device of claim 6, wherein the material is electrically conductive.

8. The device of claim 6, wherein the material is flexible.

9. The device of claim 6, wherein the transparent material is at least one of indium-tin-oxide (ITO) and copper-tin-oxide (CTO).

10. The device of claim 1, wherein the body comprises a first surface and a second surface, and wherein the first surface comprises the material.

11. The device of claim 10, wherein the first surface is a front surface of the device.

12. The device of claim 1, wherein the body comprises a first surface and a second surface, and wherein the second surface comprises the material.

13. The device of claim 12, wherein the second surface is a back surface of the device.

14. The device of claim 1, wherein the body comprises a first surface and a second surface, and wherein the first surface comprises the material and the material is transparent.

15. A device that is adapted to receive a card comprising information in machine-readable form, the device comprising:
a body, wherein at least a portion of the body is comprised of a transparent conductive material.

16. The device of claim 15, wherein the entirety of the body is comprised of the transparent conductive material.

17. The device of claim 15, wherein the transparent conductive material is adapted to attenuate at least one of an interrogating signal to be directed toward the card and a return signal to be sent from the card by approximately 1-1000 dB.

18. The device of claim 15, wherein the transparent conductive material is flexible.

19. The device of claim 18, wherein the transparent conductive material is at least one of indium-tin-oxide (ITO) and copper-tin-oxide (CTO).

20. The device of claim 15, wherein the information is confidential information.

21. The device of claim 15, wherein the body comprises a first surface and a second surface, and wherein the first surface comprises the transparent conductive material.

22. The device of claim 21, wherein the first surface is a front surface of the device.

23. The device of claim 15, wherein the body comprises a first surface and a second surface, and wherein the second surface comprises the transparent conductive material.

24. The device of claim 23, wherein the second surface is a back surface of the device.

25. The device of claim 15, wherein the body comprises a first surface and a second surface, and wherein the first surface comprises the transparent conductive material and the transparent conductive material is absent from the second surface.

26. A method, comprising:
providing a card comprising information in machine-readable form; and
positioning the card at least partially within an opening in a body of a device, wherein at least a portion of the body is comprised of a material that is adapted to attenuate an interrogating signal sent toward the card or a return signal sent from the card.

27. The method of claim 26, wherein the entirety of the body is comprised of the material.

28. The method of claim 26, wherein the material is adapted to attenuate at least one of the interrogating signal and the return signal by approximately 1-1000 dB.

29. The device of claim 26, wherein the information is confidential information.

30. The method of claim 26, wherein the material comprises a metal.

31. The method of claim 26, wherein the material is a transparent material.

32. The method of claim 31, wherein the material is electrically conductive.

33. The method of claim 31, wherein the material is flexible.

34. The method of claim 31, wherein the transparent material is at least one of indium-tin-oxide (ITO) and copper-tin-oxide (CTO).

35. The method of claim 26, wherein the body comprises a first surface and a second surface, and wherein the first surface comprises the material.

36. The method of claim 26, wherein the body comprises a first surface and a second surface, and wherein the first surface comprises the material and the material is transparent.
